(19) United States
(12) Patent Application Publication
(10) Pub. No.: US 2014/0019716 A1
(43) Pub. Date: Jan. 16, 2014

(54) PLATEABLE DIFFUSION BARRIER TECHNIQUES

(71) Applicant: Christopher J. Jezewski, Hillsboro, OR (US)

(72) Inventor: Christopher J. Jezewski, Hillsboro, OR (US)

(21) Appl. No.: 13/545,910

(22) Filed: Jul. 10, 2012

(51) Int. Cl. H01L 23/532; G06F 15/76; G06F 9/02; H01L 21/768

(52) U.S. Cl. 712/32; 257/751; 438/643; 257/E23.155; 257/E21.584; 712/E09.002

(57) ABSTRACT

Techniques are disclosed for forming a directly plateable diffusion barrier within an interconnect structure to prevent diffusion of interconnect fill metal into surrounding dielectric material and lower metal layers. The barrier can be used in back-end interconnect metallization processes and, in an embodiment, renders a seed layer unnecessary. In accordance with various example embodiments, the barrier can be implemented, for instance, as: (1) a single layer of ruthenium silicide (RuSiₓ) or ruthenium silicide nitride (RuSiₓN_{y}); (2) a bi-layer of Ru/RuSiₓ, RuSiₓ/Ru, Ru/RuSiₓN_{y}, or RuSiₓN_{y}/Ru; or (3) a tri-layer of Ru/RuSiₓ/Ru or Ru/RuSiₓN_{y}/Ru. In some embodiments, Si and/or N concentrations can be adjusted to alter the barrier's degree of diffusion protection, receptiveness to the fill metal, and/or electrical conductivity.

### BACKGROUND

In the manufacture of integrated circuits (ICs), interconnects can be formed using back-end metallization techniques. However, there are a number of non-trivial challenges associated with such techniques, and continued process scaling will tend to exacerbate such problems.

### BRIEF DESCRIPTION OF THE DRAWINGS

FIG. 1 is a cross-section view of an integrated circuit (IC) patterned for formation therein of an interconnect structure, in accordance with an embodiment of the present invention.

FIG. 2A is a cross-section view of the patterned IC of FIG. 1 after deposition of a barrier thereon, in accordance with an embodiment of the present invention.

FIG. 2B is a partial cross-section view of a single-layer barrier configured in accordance with an embodiment of the present invention.

FIG. 2C is a partial cross-section view of a bi-layer barrier configured in accordance with an embodiment of the present invention.

FIG. 2D is a partial cross-section view of a bi-layer barrier configured in accordance with an embodiment of the present invention.

FIG. 2E is a partial cross-section view of a tri-layer barrier configured in accordance with an embodiment of the present invention.

FIG. 3 is a cross-section view of the IC of FIG. 2A after deposition of an interconnect fill metal, in accordance with an embodiment of the present invention.

FIG. 4 is a cross-section view of the IC of FIG. 3 after planarizing thereof, in accordance with an embodiment of the present invention.

FIG. 5 is a partial cross-section view of a stacked IC, configured in accordance with an embodiment of the present invention.

FIG. 6 illustrates a computing system implemented with integrated circuit (IC) structures or devices formed by implementing one or more of the disclosed techniques in accordance with an example embodiment of the present invention.

For purposes of clarity, not every component may be labeled in every drawing. Furthermore, as will be appreciated in light of this disclosure, the figures are not necessarily drawn to scale or intended to limit the claimed invention to the specific configurations shown. For instance, while some figures generally indicate straight lines, right angles, and smooth surfaces, an actual implementation of the disclosed techniques may produce less than perfect straight lines, right angles, and some features may have surface topology or otherwise be non-smooth, given real world limitations of processing equipment and materials. In short, the figures are provided merely to show example structures.

### DETAILED DESCRIPTION

Techniques are disclosed for forming a directly plateable diffusion barrier within an interconnect structure to prevent diffusion of interconnect fill metal into surrounding dielectric material and lower metal layers. The barrier can be used in back-end interconnect metallization processes and, in an embodiment, renders a seed layer unnecessary. In accordance with various example embodiments, the barrier can be implemented, for instance, as: (1) a single layer of ruthenium silicide (RuSiₓ) or ruthenium silicide nitride (RuSiₓN_{y}); (2) a bi-layer of Ru/RuSiₓ, RuSiₓ/Ru, Ru/RuSiₓN_{y}, or RuSiₓN_{y}/Ru; or (3) a tri-layer of Ru/RuSiₓ/Ru or Ru/RuSiₓN_{y}/Ru. In some embodiments, Si and/or N concentrations can be adjusted to alter the barrier's degree of diffusion protection, receptiveness to the fill metal, and/or electrical conductivity. Some embodiments can be used to produce interconnect structures having feature sizes in the 15 nm node and beyond. The disclosed techniques can be implemented in the fabrication of a wide range of integrated circuits (ICs) and other devices. Numerous configurations and variations will be apparent in light of this disclosure.

General Overview

One existing approach/technique to forming back-end interconnect structures involves using a physical vapor deposition (PVD)/sputtering process to deposit a tantalum nitride (TaN) barrier layer and a tantalum (Ta) adhesion layer (i.e., to form a TaN/Ta stack) into a trench or via that has been patterned in a dielectric material. Alternatively, a titanium nitride (TiN) barrier layer and a titanium (Ti) adhesion layer (i.e., a TiN/Ti stack) may be provided in similar fashion. In either case, a copper (Cu) seed layer is then deposited into the trench/via by a PVD/sputtering process. The TaN (or TiN) barrier layer reduces diffusion of the Cu into the underlying dielectric layer, while the Ta (or Ti) adhesion layer provides nucleation, wetting, and adhesion to the subsequently deposited Cu seed layer. The conductivity and surface chemistry of the Cu seed layer permits use of an electroplating process to fill the trench/via with Cu to form the desired back-end interconnect. Finally, the interconnect structure is polished or otherwise planarized by chemical-mechanical planarization (CMP) and a layer of an etch stop material may be deposited on the resultant topology.

However, as previously noted, there are a number of non-trivial challenges involved in metallization of back-end interconnects. For instance, the aforementioned TaN/Ta/Cu seed and TiN/Ti/Cu seed stacks normally are deposited as a film having a relatively substantial thickness (e.g., 15 nm or greater). Therefore, such barrier/seed layers do not lend themselves to process scaling for use, for example, in achieving aggressively scaled feature dimensions in the 15 nm process node and beyond (e.g., 10 nm node and beyond). Also, there exist some techniques/approaches that utilize pure noble metals which are plateable. However, these plateable metals do not provide a suitable diffusion barrier to keep the Cu interconnect fill separate from the surrounding dielectric and lower metal layers.

Thus, and in accordance with an embodiment of the present invention, techniques are disclosed for forming a directly plateable diffusion barrier within an interconnect structure. In accordance with an embodiment, the barrier/liner can be implemented, for example, as: (1) a single layer of ruthenium silicide (RuSiₓ) or ruthenium silicide nitride (RuSiₓN_{y}); (2) a bi-layer of Ru/RuSiₓ, RuSiₓ/Ru, Ru/RuSiₓN_{y}, or RuSiₓN_{y}/Ru; or (3) a tri-layer of Ru/RuSiₓ/Ru or Ru/RuSiₓN_{y}/Ru. In some cases, the barrier/liner can prevent or otherwise minimize diffusion of interconnect fill metal (e.g., copper) into surrounding dielectric material and lower metal layers, in accordance with an embodiment.

Furthermore, and in accordance with an embodiment, the concentrations of silicon (Si) and/or nitrogen (N) within the barrier/liner can be tailored or otherwise customized to change various performance characteristics of the barrier. For instance, in some cases, concentration adjustments can be made to alter one or more of the barrier's: (1) degree of diffusion protection; (2) receptiveness to direct deposition of the interconnect fill metal (e.g., copper); and/or (3) electrical conductivity (e.g., to an underlying conductive layer, wafer/substrate, etc.).

In accordance with an embodiment, a barrier/liner configured using the disclosed techniques can be used in back-end interconnect metallization processes and, in some specific example embodiments, may permit electroplating (or other deposition) of the interconnect fill metal directly on the exposed barrier/liner. In some such cases, and in accordance with an embodiment, this may render formation/deposition of an intermediate seed layer unnecessary. In some instances, the barrier may do so while enabling robust gap-filling/metallization of the interconnect structure without substantially degrading structural reliability thereof. However, as will be appreciated in light of this disclosure, and in accordance with an embodiment, an intermediate seed layer (and/or other intermediate layer) can be included in some instances between the barrier/liner and the interconnect fill metal.

As will be appreciated in light of this disclosure, a plateable diffusion barrier/liner provided in accordance with an embodiment of the present invention may be of substantially smaller dimensions (e.g., thickness), and thus have a substantially lower profile, as compared with the aforementioned TaN/Ta/Cu seed and TiN/Ti/Cu seed PVD layers utilized in existing approaches. In some cases, the disclosed techniques can be used, in accordance with an embodiment, to form a diffusion barrier/liner having a thickness in the range of less than or equal to about 10 nm (e.g., in the range of about 1-6 nm). Thus, and in accordance with an embodiment, one or more of the disclosed techniques can be used, for example, in the production of interconnect structures having feature sizes in the 15 nm node and beyond.

Some embodiments of the present invention can be used, for instance, in the fabrication of interconnect structures (both inter-chip and intra-chip interconnects) which may be implemented in a wide range of integrated circuits (ICs) and other components/devices. As will be appreciated further in light of this disclosure, and in accordance with an embodiment, use of the techniques provided herein may be detected, for example, by cross-section analysis and/or materials analysis of a given IC or other device that has an interconnect structure which includes a plateable diffusion barrier/liner (e.g., single layer, bi-layer, or tri-layer barrier including RuSiₓ or RuSiₓN_{y}) configured as described herein.

Methodology and Structure

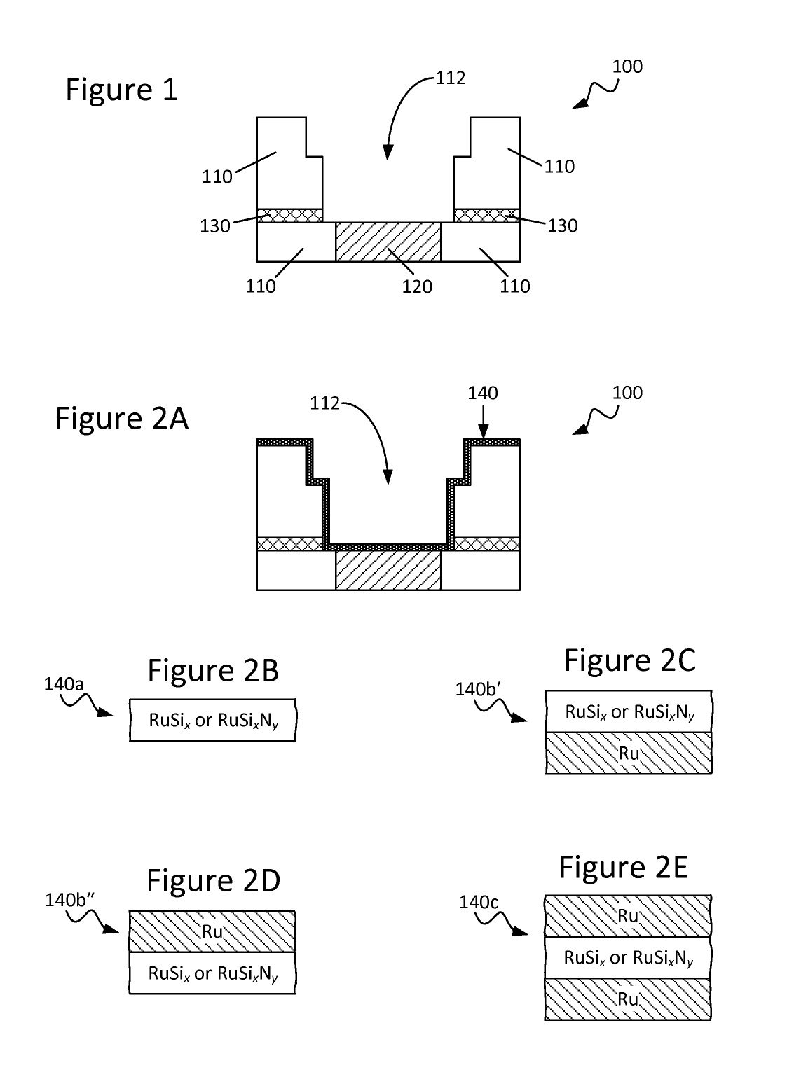

FIG. 1 is a cross-section view of an integrated circuit (IC) 100 patterned for formation therein of an interconnect structure 112, in accordance with an embodiment of the present invention. As can be seen, IC 100 may comprise, in part, a layer of insulator material (e.g., an inter-layer dielectric or ILD) 110. ILD 110 may be patterned, for example, for formation therein of one or more interconnect structures 112. In accordance with an embodiment, the disclosed techniques can be implemented with a wide variety of interconnect structures 112, including: (1) dual-damascene structures (e.g., a trench with an underlying via, like the specific example shown in FIG. 1); (2) single-damascene structures; and/or (3) any other interconnect structures which may undergo back-end metallization processes. As will be appreciated, patterning of a given interconnect structure 112 in ILD 110 may be performed, for example, using standard lithography techniques including via and trench patterning and subsequent etch processes followed by polishing, cleans, etc., as typically done. As will be appreciated further, the patterning and etch processes can be carried out, for instance, using wet and/or dry etch techniques. The dimensions of a given patterned interconnect structure 112 can vary or otherwise be customized depending on the application or end-use.

In accordance with an embodiment, the disclosed techniques can be implemented with a wide variety of ILD 110 dielectric materials (e.g., low-K, high-K, or otherwise). For instance, in some specific example embodiments, the disclosed techniques can be used with an ILD 110 comprising one or more of: (1) an oxide (e.g., silicon dioxide, silicon oxide, carbon-doped oxide, etc.); (2) a nitride (e.g., silicon nitride); (3) a polymer (e.g., perfluorocyclobutane or polytetrafluoroethylene); (4) a phosphosilicate glass (PSG); (5) a fluorosilicate glass (FSG); (6) an organosilicate glass (OSG) (e.g., silsesquioxane or siloxane); (7) a combination thereof; and/or (8) any other suitable dielectric material. Numerous other suitable materials for ILD 110 will be apparent in light of this disclosure.

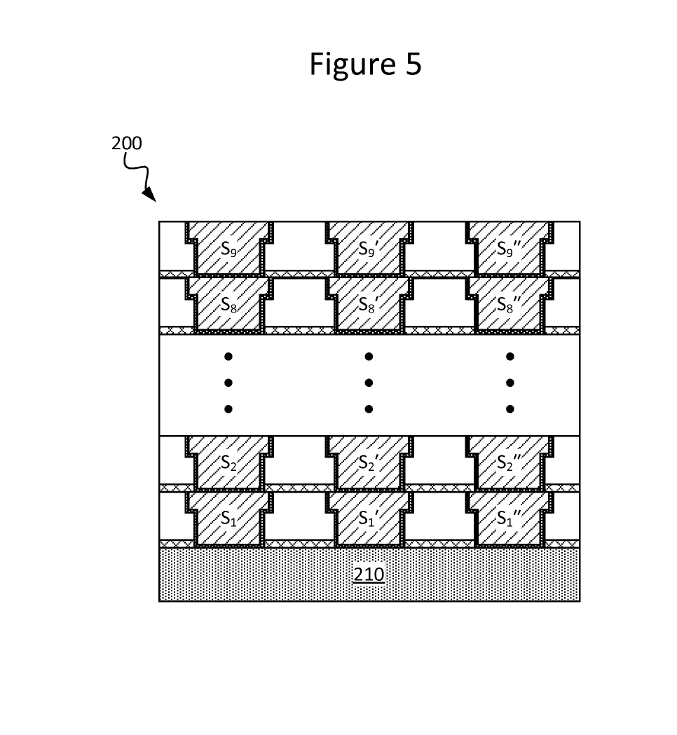

As will be appreciated further, ILD 110 can be deposited (e.g., on a substrate, wafer, or other suitable surface, such as that described below with reference to FIG. 5) using any of a wide range of suitable deposition techniques, such as, but not limited to: (1) physical vapor deposition (PVD); (2) chemical vapor deposition (CVD); and/or (3) spin-on deposition (SOD). Other suitable configurations, materials, and/or deposition techniques for ILD 110 will depend on a given application and will be apparent in light of this disclosure.

In some cases, interconnect structure 112 may have one or more lower metal layers 120 located beneath it. Lower metal layer 120 may comprise, in some cases, an electrically conductive metal such as: (1) copper (Cu); (2) silver (Ag); (3) aluminum (Al); (4) gold (Au); (5) an alloy thereof; and/or (6) any other suitable electrically conductive metal. Also, in some cases, interconnect structure 112 may have an adjacent or otherwise proximate etch stop layer 130. As will be appreciated in light of this disclosure, etch stop 130 can be configured as conventionally done. Other suitable configurations and/or materials for lower metal layer(s) 120 and etch stop 130 will depend on a given application and will be apparent in light of this disclosure.

FIG. 2A is a cross-section view of the patterned IC 100 of FIG. 1 after deposition of a barrier 140 thereon, in accordance with an embodiment of the present invention. In various embodiments, barrier 140 generally may comprise a material having the ability: (1) to sufficiently limit (e.g., prevent or otherwise minimize) diffusion of an interconnect fill metal 150 (e.g., Cu) into the surrounding ILD 110 and any lower metal layers 120; (2) to provide sufficiently high electrical conductivity to maintain suitable electronic contact; and/or (3) to permit direct electroplating (or other deposition) of the interconnect fill metal 150 thereon without requiring an intermediate seed layer.

Numerous configurations of barrier 140 are possible. For example, in some cases, barrier 140 can be configured as in FIG. 2B, which is a partial cross-section view of a single-layer barrier 140a configured in accordance with an embodiment of the present invention. As can be seen, a single layer of ruthenium silicide (RuSiₓ) or ruthenium silicide nitride (RuSiₓN_{y}) can be deposited within interconnect structure 112. In some other example cases, barrier 140 can be configured as in FIG. 2C, which is a partial cross-section view of a bi-layer barrier 140b′ configured in accordance with an embodiment of the present invention. As can be seen, a bi-layer film of Ru/RuSiₓ or Ru/RuSiₓN_{y} can be deposited within interconnect structure 112 such that the Ru layer of bi-layer barrier 140b′ is in contact with ILD 110. In some other example cases, however, barrier 140 can be configured as in FIG. 2D, which is a partial cross-section view of a bi-layer barrier 140b″ configured in accordance with an embodiment of the present invention. As can be seen, a bi-layer film of RuSiₓ/Ru or RuSiₓN_{y}/Ru can be deposited within interconnect structure 112 such that the RuSiₓ or RuSiₓN_{y} layer of bi-layer barrier 140b″ is in contact with ILD 110. In some still other example cases, barrier 140 can be configured as in FIG. 2E, which is a partial cross-section view of a tri-layer barrier 140c configured in accordance with an embodiment of the present invention. As can be seen, a tri-layer film of Ru/RuSiₓ/Ru or of Ru/RuSiₓN_{y}/Ru can be deposited within interconnect structure 112. Furthermore, in some cases, barrier 140 may include one or more impurities (e.g., carbon, oxygen, hydrogen, argon, helium, and/or other intended or unintended contaminants/constituents), in accordance with an embodiment. In some such instances, the one or more impurities may have a concentration in the range of about 10% or less (e.g., about 5-10%, about 0-5%, or any other sub-range within the range of about 10% or less). Other suitable configurations for a ruthenium silicide and/or ruthenium silicide nitride barrier 140 will be apparent in light of this disclosure.

In accordance with an embodiment, the concentration of silicon (Si) and/or nitrogen (N) within a given barrier 140 can be tailored or otherwise customized to change various performance characteristics thereof. For example, and in accordance with an embodiment, barrier 140 can be implemented with: (1) a Si concentration in the range of less than or equal to about 60% (e.g., about 40-60%, about 20-40%, about 0.05-20%, or any other sub-range within the range of about 60% or less); and/or (2) a N concentration in the range of less than or equal to about 60% (e.g., about 40-60%, about 20-40%, about 0.05-20%, or any other sub-range within the range of about 60% or less). Other suitable Si and/or N concentration ranges/sub-ranges for barrier 140 will depend on a given application and will be apparent in light of this disclosure.

In some cases, concentration adjustments can be made to alter the degree of diffusion protection offered by barrier 140 (e.g., increasing the concentration of Si and/or N may result in a general increase in diffusion prevention). Also, in some cases, adjustments can be made to alter the receptiveness of barrier 140 to the interconnect fill metal 150 (e.g., increasing the concentration of Si and/or N may result in a general increase in the receptiveness of barrier 140, for instance, to direct deposition of Cu interconnect fill metal 150). Furthermore, in some cases, adjustments can be made to alter the electrical conductivity of barrier 140 (e.g., increasing the concentration of Si and/or N may result in a general increase in conductivity for barrier 140 to an underlying wafer/substrate).

In accordance with an embodiment, barrier 140 can be deposited using a wide variety of techniques, including chemical vapor deposition (CVD) (e.g., plasma-enhanced CVD) and atomic layer deposition (ALD). In some embodiments, barrier 140 can be deposited as a conformal layer (e.g., substantially uniform thickness) which covers the topology of the interconnect structure 112 patterned in ILD 110. However, the claimed invention is not so limited, as in some other embodiments barrier 140 can be configured with a non-uniform or otherwise varying thickness. In one specific example embodiment, barrier 140 can be deposited with a thickness in the range of less than or equal to about 10 nm (e.g., in the range of about 1-5 nm, 6-9 nm, or any other sub-range within the range of about 10 nm or less). Some other embodiments may have a barrier 140 having a thickness in the range of 10-100 nm or within any sub-range of that range. In some still other embodiments, portions of barrier 140 may have a thickness within a first range while other portions of barrier 140 have a thickness in a second range. Furthermore, and in accordance with an embodiment, some configurations of barrier 140 can be implemented regardless of interconnect structure 112 geometry/configuration (e.g., uniform or non-uniform sidewalls, one or more tapered dimensions, etc.). Other suitable deposition techniques, thickness ranges, intentional width variation or other non-uniformities, and/or configurations for barrier 140 will depend on a given application and will be apparent in light of this disclosure.

As previously noted, barrier 140 can be configured, in accordance with an embodiment of the present invention, to directly receive (e.g., by electroplating or other suitable deposition process) interconnect fill metal 150 without requiring a seed layer there between. As will be appreciated, in some cases this may eliminate the seed layer deposition process step typically required by existing approaches/techniques. Also, as previously noted, barrier 140 may permit omission of such a seed layer while still providing a given back-end interconnect structure 112 with robust gap-filling/metallization and without substantially degrading structural reliability thereof.

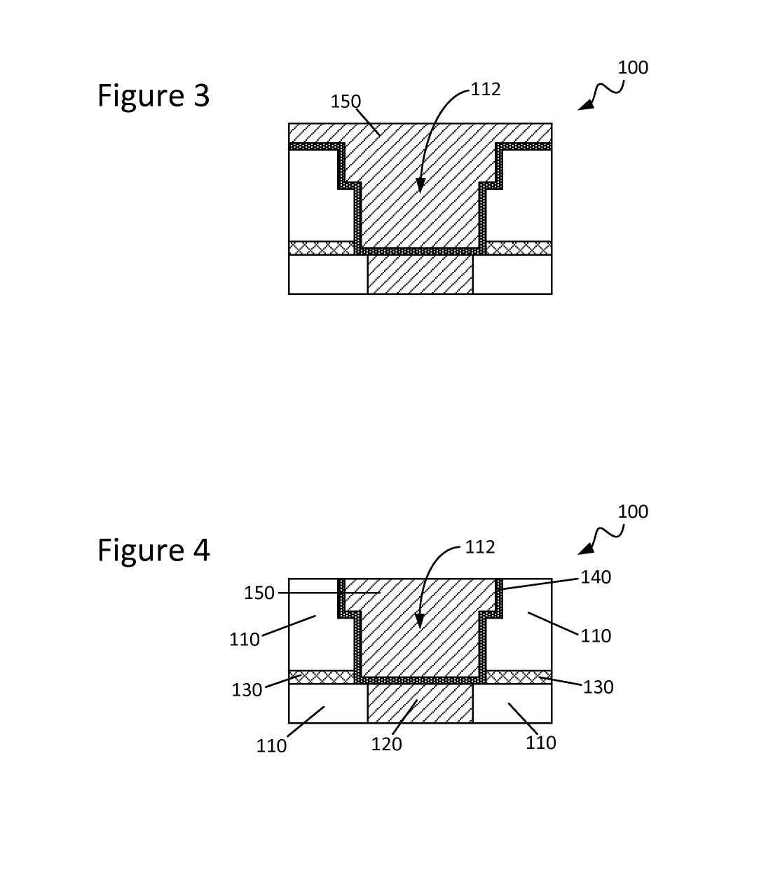

FIG. 3 is a cross-section view of the IC 100 of FIG. 2A after deposition of an interconnect fill metal 150, in accordance with an embodiment of the present invention. As can be seen, interconnect structure 112 can be gap-filled with an interconnect fill metal 150 after deposition of barrier 140. In accordance with an embodiment, a wide variety of deposition processes can be used to gap-fill interconnect structure 112, including, but not limited to: (1) electroplating; (2) electroless deposition; (3) chemical vapor deposition (CVD); and/or (4) any other gap-fill technique/process suitable for back-end metallization. As previously discussed, in some embodiments interconnect fill metal 150 can be directly deposited on barrier 140 without any intermediate material layers (e.g., seed layer, adhesion layer, etc.). However, the claimed invention is not so limited, as in some other example instances, one or more intermediate layers optionally may be deposited between barrier 140 and interconnect fill metal 150, if so desired. In some cases, the quantity of interconnect fill metal 150 may be sufficient to overfill interconnect structure 112. As discussed below with reference to FIG. 4, any undesired excess of interconnect fill metal 150 can be removed subsequently, for example, with a suitable etch or planarization process.

In accordance with an embodiment, interconnect fill metal 150 may comprise, an electrically conductive metal, such as, but not limited to: (1) copper (Cu); (2) silver (Ag); (3) aluminum (Al); (4) gold (Au); (5) alloys thereof; and/or (6) any other suitably electrically conductive metal. In some example cases, interconnect fill metal 150 may comprise the same material(s) as lower metal layer 120. Other suitable deposition processes and/or materials for interconnect fill metal 150 will depend on a given application and will be apparent in light of this disclosure.

FIG. 4 is a cross-section view of the IC 100 of FIG. 3 after planarizing thereof, in accordance with an embodiment of the present invention. IC 100 can be polished or otherwise planarized, for example, by chemical-mechanical planarization (CMP) or any other suitable polishing/planarization technique/process. As can be seen, planarization of IC 100 may be performed to remove, in part, any undesired excess of: (1) interconnect fill metal 150; and/or (2) barrier 140.

Thereafter, and in accordance with an embodiment, an etch stop layer optionally may be deposited on IC 100. As will be appreciated, this optional etch stop layer may comprise one or more of the same materials, for example, as etch stop layer 130, discussed above with reference to FIG. 1.

FIG. 5 is a partial cross-section view of a stacked IC 200, configured in accordance with an embodiment of the present invention. As can be seen, a multi-layer or otherwise stacked IC 200 can be configured with a plurality of interconnect structures S₁-S₉, S₁′-S₉′, S₁″-S₉″, etc., formed using one or more of the techniques disclosed herein, in accordance with an embodiment. In the specific example embodiment illustrated in FIG. 5, a plurality of dual-damascene interconnect structures are shown. However, as previously noted with respect to FIG. 1, the claimed invention is not limited to dual-damascene interconnect structures, and in some other embodiments one or more single-damascene interconnect structures and/or other back-end interconnect structures formed by the techniques disclosed herein can be implemented in stacked IC 200. In a more general sense, interconnects configured as described herein can be implemented having any shape suitable for a given application and set of desired performance criteria.

In accordance with an embodiment, substrate 210 can be implemented with any suitable materials, including, but not limited to, metal, silicon (Si), germanium (Ge), III-V materials, oxide, nitride, combinations thereof, or other suitable semiconductor substrate materials. Substrate 210 may be configured, for example, as a bulk substrate, a semiconductor-on-insulator (XOI, where X is a semiconductor material such as silicon, germanium, or germanium-enriched silicon), or a multi-layered structure. Substrate 210 may be of any given thickness, as desired for a given application. In some specific example instances, substrate 210 may be a semiconductor wafer.

It should be noted that the layouts of IC 100, stacked IC 200, and the various elements depicted therein/therewith are not necessarily drawn to scale or intended to limit the claimed invention in any way. For instance, while the cross-section views shown in FIGS. 1, 2A-2D, 3, 4, and 5 generally indicate linear surfaces, uniform thicknesses, and feature symmetry, an actual implementation of the techniques disclosed herein may have non-linear and/or non-uniform characteristics or otherwise be variable, given real-world limitations of the processing equipment and techniques used. In short, FIGS. 1, 2A-2D, 3, 4, and 5 are provided merely to show a few possible example interconnect structures and IC layout schemes configured in accordance with one or more embodiments of the present invention.

Example System

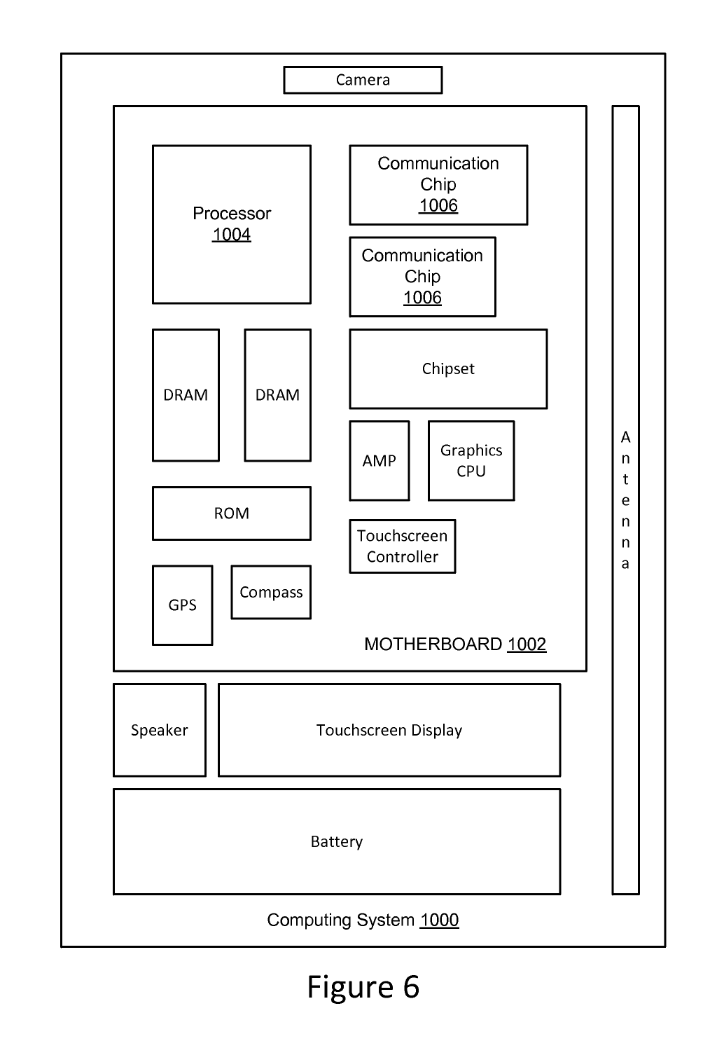

FIG. 6 illustrates a computing system 1000 implemented with integrated circuit (IC) structures or devices formed by implementing one or more of the disclosed techniques in accordance with an example embodiment of the present invention. As can be seen, the computing system 1000 houses a motherboard 1002. The motherboard 1002 may include a number of components, including, but not limited to, a processor 1004 and at least one communication chip 1006, each of which can be physically and electrically coupled to the motherboard 1002, or otherwise integrated therein. As will be appreciated, the motherboard 1002 may be, for example, any printed circuit board, whether a main board, a daughterboard mounted on a main board, or the only board of system 1000, etc. Depending on its applications, computing system 1000 may include one or more other components that may or may not be physically and electrically coupled to the motherboard 1002. These other components may include, but are not limited to, volatile memory (e.g., DRAM), non-volatile memory (e.g., ROM), a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 1000 may include one or more integrated circuit structures or devices formed using one or more of the diffusion barrier techniques disclosed herein, in accordance with an example embodiment of the present invention. In some embodiments, multiple functions can be integrated into one or more chips (e.g., for instance, note that the communication chip 1006 can be part of or otherwise integrated into the processor 1004).

The communication chip 1006 enables wireless communications for the transfer of data to and from the computing system 1000. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1006 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 1000 may include a plurality of communication chips 1006. For instance, a first communication chip 1006 may be dedicated to shorter range wireless communications such as Wi-Fi and Bluetooth and a second communication chip 1006 may be dedicated to longer range wireless communications such as GPS, EDGE, GPRS, CDMA, WiMAX, LTE, Ev-DO, and others.

The processor 1004 of the computing system 1000 includes an integrated circuit die packaged within the processor 1004. In some embodiments of the present invention, the integrated circuit die of the processor includes onboard memory circuitry that is implemented with one or more integrated circuit structures or devices formed using one or more of the diffusion barrier techniques, as variously described herein. The term “processor” may refer to any device or portion of a device that processes, for instance, electronic data from registers and/or memory to transform that electronic data into other electronic data that may be stored in registers and/or memory.

The communication chip 1006 also may include an integrated circuit die packaged within the communication chip 1006. In accordance with some such example embodiments, the integrated circuit die of the communication chip includes one or more integrated circuit structures or devices formed using one or more of the diffusion barrier techniques as described herein. As will be appreciated in light of this disclosure, note that multi-standard wireless capability may be integrated directly into the processor 1004 (e.g., where functionality of any chips 1006 is integrated into processor 1004, rather than having separate communication chips). Further note that processor 1004 may be a chip set having such wireless capability. In short, any number of processor 1004 and/or communication chips 1006 can be used. Likewise, any one chip or chip set can have multiple functions integrated therein.

In various implementations, the computing device 1000 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device that processes data or employs one or more integrated circuit structures or devices formed using one or more of the plateable diffusion barrier techniques, as described herein.

Numerous embodiments will be apparent in light of this disclosure. One example embodiment of the present invention provides an interconnect structure including a barrier deposited over a trench and/or via formed in a dielectric material, wherein the barrier includes a layer of ruthenium silicide (RuSiₓ) or ruthenium silicide nitride (RuSiₓN_{y}) and an electrically conductive fill metal deposited over the barrier. In some cases, the barrier further includes a layer of ruthenium (Ru). In some other cases, the barrier further includes two distinct layers of ruthenium (Ru), the layer of RuSiₓ or RuSiₓN_{y} disposed there between. In some instances, the barrier is deposited by a chemical vapor deposition (CVD) process or an atomic layer deposition (ALD) process. In one specific example case, the barrier has a thickness of less than or equal to about 10 nm. In some cases, the barrier reduces diffusion of the electrically conductive fill metal into at least one of the dielectric material and/or a lower metal layer. In some example instances, the barrier at least one of has a concentration of silicon (Si) in the range of less than or equal to about 60% and/or has a concentration of nitrogen (N) in the range of less than or equal to about 60%. In some cases, the electrically conductive fill metal comprises copper (Cu), aluminum (Al), silver (Ag), gold (Au), or an alloy thereof. In some instances, the electrically conductive fill metal is deposited by an electroplating process, an electroless deposition process, or a chemical vapor deposition (CVD) process. In some cases, the structure has been planarized to remove excess barrier material and excess electrically conductive fill metal. In some such cases, the structure further includes an etch stop layer deposited on the resultant interconnect structure. Numerous variations will be apparent. For instance, another embodiment provides a mobile computing system comprising an integrated circuit that is configured with an interconnect structure as variously described in this paragraph.

Another example embodiment of the present invention provides a method of forming an interconnect structure, the method including depositing a barrier over a trench and/or via formed in a dielectric material, wherein the barrier comprises a layer of ruthenium silicide (RuSiₓ) or ruthenium silicide nitride (RuSiₓN_{y}) and depositing an electrically conductive fill metal over the barrier. In some cases, the barrier further includes a layer of ruthenium (Ru). In some other cases, the barrier further includes two distinct layers of ruthenium (Ru), the layer of RuSiₓ or RuSiₓN_{y} disposed there between. In some instances, depositing the barrier includes using a chemical vapor deposition (CVD) process or an atomic layer deposition (ALD) process. In one specific example case, the barrier has a thickness of less than or equal to about 10 nm. In some cases, the barrier reduces diffusion of the electrically conductive fill metal into at least one of the dielectric material and/or a lower metal layer. In some example instances, the barrier at least one of has a concentration of silicon (Si) in the range of less than or equal to about 60% and/or has a concentration of nitrogen (N) in the range of less than or equal to about 60%. In some cases, the method further includes, prior to depositing the barrier, forming the trench and/or via in the dielectric material. In some cases, the electrically conductive fill metal comprises copper (Cu), aluminum (Al), silver (Ag), gold (Au), or an alloy thereof. In some instances, depositing the electrically conductive fill metal includes using an electroplating process, an electroless deposition process, or a chemical vapor deposition (CVD) process. In some cases, the method further includes, after depositing the electrically conductive fill metal over the barrier, planarizing the interconnect structure to remove excess barrier material and excess electrically conductive metal. In some such cases, the method further includes, after planarizing the interconnect structure, depositing an etch stop layer on the resultant interconnect structure.

Another embodiment provides a mobile computing system that includes a printed circuit board, a processor operatively coupled to the printed circuit board, a memory operatively coupled to the printed circuit board and in communication with the processor, and a wireless communication chip operatively coupled to the printed circuit board and in communication with the processor. At least one of the processor, communication chip, and/or the memory comprises an interconnect structure. The interconnect structure includes a barrier deposited over a trench and/or via formed in a dielectric material, wherein the barrier comprises a layer of ruthenium silicide (RuSiₓ) or ruthenium silicide nitride (RuSiₓN_{y}), and an electrically conductive fill metal deposited over the barrier. The mobile system may be, for example, a cellular telephone, a laptop, a smartphone, a set-top box, or a tablet computer. In some cases, the barrier further comprises a layer of ruthenium (Ru). In some cases, the barrier further comprises two distinct layers of ruthenium (Ru), the layer of RuSix or RuSixNy disposed there between.

Another example embodiment of the present invention provides an integrated circuit including a dielectric material deposited on a substrate, wherein the dielectric material has a trench and/or via formed therein, a barrier deposited over the trench and/or via, wherein the barrier comprises a layer of ruthenium silicide (RuSiₓ) or ruthenium silicide nitride (RuSiₓN_{y}), and a quantity of copper (Cu) deposited over the barrier. In some cases, the barrier further comprises a layer of ruthenium (Ru). In some other cases, the barrier further comprises two distinct layers of ruthenium (Ru), the layer of RuSiₓ or RuSiₓN_{y} disposed there between. In some instances, the barrier reduces diffusion of the Cu into at least one of the dielectric material and/or a lower metal layer. In some instances, the barrier and the Cu have an intermediate layer there between.

The foregoing description of the embodiments of the invention has been presented for the purposes of illustration and description. It is not intended to be exhaustive or to limit the invention to the precise form disclosed. Many modifications and variations are possible in light of this disclosure. It is intended that the scope of the invention be limited not by this detailed description, but rather by the claims appended hereto.

1. An interconnect structure comprising:
a barrier deposited over a trench and/or via formed in a dielectric material, wherein the barrier comprises a layer of ruthenium silicide nitride (RuSiₓN_{y}); and
an electrically conductive fill metal deposited over the barrier.

2. The structure of claim 1, wherein the barrier further comprises a layer of ruthenium (Ru).

3. The structure of claim 1, wherein the barrier further comprises two distinct layers of ruthenium (Ru), the layer of RuSiₓN_{y} disposed there between.

4. The structure of claim 1, wherein the barrier is deposited by a chemical vapor deposition (CVD) process or an atomic layer deposition (ALD) process.

5. The structure of claim 1, wherein the barrier has a thickness of less than or equal to about 10 nm.

6. The structure of claim 1, wherein the barrier reduces diffusion of the electrically conductive fill metal into at least one of the dielectric material and/or a lower metal layer.

7. The structure of claim 1, wherein the barrier at least one of has a concentration of silicon (Si) in the range of less than or equal to about 60% and/or has a concentration of nitrogen (N) in the range of less than or equal to about 60%.

8. The structure of claim 1, wherein the electrically conductive fill metal comprises copper (Cu), aluminum (Al), silver (Ag), gold (Au), or an alloy thereof.

9. The structure of claim 1, wherein the electrically conductive fill metal is deposited by an electroplating process, an electroless deposition process, or a chemical vapor deposition (CVD) process.

10. The structure of claim 1, wherein the structure has been planarized to remove excess barrier material and excess electrically conductive fill metal.

11. The structure of claim 10 further comprising an etch stop layer deposited on the resultant interconnect structure.

12. A mobile computing system comprising an integrated circuit configured with the interconnect structure of claim 1.

13. A method of forming an interconnect structure, the method comprising:
depositing a barrier over a trench and/or via formed in a dielectric material, wherein the barrier comprises a layer of ruthenium silicide nitride (RuSiₓN_{y}); and
depositing an electrically conductive fill metal over the barrier.

14. The method of claim 13, wherein the barrier further comprises a layer of ruthenium (Ru).

15. The method of claim 13, wherein the barrier further comprises two distinct layers of ruthenium (Ru), the layer of RuSiₓN_{y} disposed there between.

16. The method of claim 13, wherein depositing the barrier comprises using a chemical vapor deposition (CVD) process or an atomic layer deposition (ALD) process.

17. The method of claim 13, wherein the barrier has a thickness of less than or equal to about 10 nm.

18. The method of claim 13, wherein the barrier reduces diffusion of the electrically conductive fill metal into at least one of the dielectric material and/or a lower metal layer.

19. The method of claim 13, wherein the barrier at least one of has a concentration of silicon (Si) in the range of less than or equal to about 60% and/or has a concentration of nitrogen (N) in the range of less than or equal to about 60%.

20. The method of claim 13, wherein prior to depositing the barrier, the method further comprises forming the trench and/or via in the dielectric material.

21. The method of claim 13, wherein the electrically conductive fill metal comprises copper (Cu), aluminum (Al), silver (Ag), gold (Au), or an alloy thereof.

22. The method of claim 13, wherein depositing the electrically conductive fill metal comprises using an electroplating process, an electroless deposition process, or a chemical vapor deposition (CVD) process.

23. The method of claim 13, wherein after depositing the electrically conductive fill metal over the barrier, the method further comprises planarizing the interconnect structure to remove excess barrier material and excess electrically conductive metal.

24. The method of claim 23, wherein after planarizing the interconnect structure, the method further comprises depositing an etch stop layer on the resultant interconnect structure.

25. A mobile computing system, comprising:
a printed circuit board;
a processor operatively coupled to the printed circuit board;
a memory operatively coupled to the printed circuit board and in communication with the processor; and
a wireless communication chip operatively coupled to the printed circuit board and in communication with the processor;
wherein at least one of the processor, wireless communication chip, and/or the memory includes an interconnect structure comprising:
a barrier deposited over a trench and/or via formed in a dielectric material, wherein the barrier comprises a layer of ruthenium silicide nitride (RuSiₓN_{y}); and
an electrically conductive fill metal deposited over the barrier.

26. The system of claim 25 wherein, the barrier further comprises a layer of ruthenium (Ru).

27. The structure of claim 25, wherein the barrier further comprises two distinct layers of ruthenium (Ru), the layer of RuSiₓN_{y} disposed there between.

28. An integrated circuit comprising:
a dielectric material deposited on a substrate, wherein the dielectric material has a trench and/or via formed therein;
a barrier deposited over the trench and/or via, wherein the barrier comprises a layer of ruthenium silicide nitride (RuSiₓN_{y}); and
a quantity of copper (Cu) deposited over the barrier.

29. The integrated circuit of claim 28, wherein the barrier further comprises a layer of ruthenium (Ru).

30. The integrated circuit of claim 28, wherein the barrier further comprises two distinct layers of ruthenium (Ru), the layer of RuSiₓN_{y} disposed there between.

31. The integrated circuit of claim 28, wherein the barrier and the Cu have an intermediate layer there between.
